(19) United States
(12) Patent Application Publication
(10) Pub. No.: US 2026/0031563 A1
(43) Pub. Date: Jan. 29, 2026

(54) Latching Port Covers

(71) Applicant: Zebra Technologies Corporation, Lincolnshire, IL (US)

(72) Inventors: Tanmay Patel, Pflugerville, TX (US); Mark Fountain, Hitchin (GB); Wei-Ti Kuo, Songshan District (TW); Zichun Song, Cedar Park, IL (US)

(21) Appl. No.: 18/785,655

(22) Filed: Jul. 26, 2024

(51) Int. Cl. H01R 13/447; H05K 5/02; H05K 5/03

(52) U.S. Cl. CPC H01R 13/447; H05K 5/0221; H05K 5/03

(57) ABSTRACT

Latching port covers are disclosed herein. An example latching port cover includes a latching port cover system for a device having a port including a recessed porting area in which the port is disposed, the recessed porting area having an outer profile defined by an outer wall, a keeper mechanically coupled to the outer wall, a cover, matched with the outer profile, having an open-retained configuration permitting access to the port and a closed configuration covering the port, a latch bolt mechanically coupled to the cover, translatable between an engaged configuration and a disengaged configuration, wherein when the latch bolt is in the engaged configuration, the latch bolt interfaces with the keeper, retaining the cover in the closed configuration, a flexible member, and a magnetic clasp, the magnetic clasp retaining the cover in the open-retained configuration when the first portion magnetically engages with the second portion.

### BACKGROUND

Certain devices, such as electronic devices, personal electronic devices, mobile computers, wearable computers, tablets and other handheld electronics and similar devices often include cable ports, which may be used for connecting these devices to other devices and systems. In some cases, especially those where the device is exposed to variable environmental conditions, it may be preferable to a user that the cable ports are covered, thus preventing ingress of water, particulate matter, and other detritus present in the environment into the cable ports, which might otherwise result in damage to the cable ports or the device.

### SUMMARY

In an embodiment, the technology of the present disclosure is a latching port cover system for a device having a port, including a recessed porting area in which the port is disposed, the recessed porting area having an outer profile defined by an outer wall, a keeper mechanically coupled to the outer wall, a cover, matched with the outer profile, having an open-retained configuration permitting access to the port and a closed configuration covering the port, a latch bolt mechanically coupled to the cover, translatable between an engaged configuration and a disengaged configuration, wherein when the latch bolt is in the engaged configuration, the latch bolt interfaces with the keeper, retaining the cover in the closed configuration, a flexible member, having a first member end mechanically coupled to the cover and a second member end mechanically coupled to the device, and a magnetic clasp, including a first portion mechanically coupled to the device and a second portion mechanically coupled to the cover, the magnetic clasp retaining the cover in the open-retained configuration when the first portion magnetically engages with the second portion.

In a variation of this embodiment, the cover and the device interface via a mechanical catch distinct from the latch bolt and keeper, and the mechanical catch restricts a degree of freedom of motion of the cover when the cover is in the closed configuration.

In a variation of this embodiment, the mechanical catch includes a hook and a catch piece, wherein the hook is coupled to the cover and the catch piece is coupled to the device, and when the latch bolt is in the disengaged configuration the cover is rotatable about the catch piece via the hook through a predetermined range of rotation, and the cover is transitioned out of the closed configuration when rotated about the catch piece.

In a variation of this embodiment, the hook is configured such that when the cover is rotated beyond the predetermined range of rotation, the hook disengages from the catch piece.

In a variation of this embodiment, the hook is coupled to the cover via a pinned connection and biased by a spring such that when the cover is in the closed configuration the hook is biased towards the catch piece and remains engaged with the catch piece.

In a variation of this embodiment, the hook includes a chamfered or filleted profile, such that when the cover is not in the closed configuration and the hook is aligned with the catch piece and externally biased theretoward, the spring is counteracted such that the hook rotates about the pinned connection and engages with the catch piece.

In a variation of this embodiment, the second member end of the flexible member is coupled to the device by a tethering component which is coupled to the device, and the tethering component includes the catch piece.

In a variation of this embodiment, the tethering component houses the second portion of the magnetic clasp.

In a variation of this embodiment, the tethering component is mechanically coupled to the device via a fastener, such that the cover is separable from the device when the fastener is removed from the tethering component.

In a variation of this embodiment, the keeper may be a detent, a recess, a protrusion, or a hole.

In a variation of this embodiment, the keeper is integrally formed with the outer wall.

In a variation of this embodiment, the recessed porting area of the device includes a plurality of ports. Ports of the plurality of ports may include high definition media interface (HDMI) port, a universal series bus (USB) port, a registered jack-45 (RJ-45) port, a registered jack-11 (RJ-11) port, a tip, ring and sleeve (TRS) connector port, a video-graphics array (VGA) port, a digital video interface (DVI) port, a display port, component video ports, a serial port, or a Recommended Standard 232 (RS-232) port.

In a variation of this embodiment, the outer wall of the recessed porting area is defined by three or more constituent walls, and the outer profile of the outer wall with which the cover is matched is defined by two or more of the three or more constituent walls.

In a variation of this embodiment, the recessed porting area is substantially rectangular.

In a variation of this embodiment, when the cover is in the closed configuration the cover is defined in a first plane, when the cover is the open-retained configuration, the cover is defined in a second plane, and the first plane and the second plane are offset from one another by at least 180 degrees.

In a variation of this embodiment, the first plane and the second plane are offset by at least 270 degrees.

In a variation of this embodiment, the cover includes a deformable material disposed about a portion of the cover which abuts the outer wall when the cover is in the closed configuration.

In a variation of this embodiment, the latch bolt is biased towards the engaged configuration by a spring.

In a variation of this embodiment, the flexible member is a flexible strap.

In a variation of this embodiment, the flexible member may be constructed of a material such as nylon, metal tape, rubber, silicone, or combinations thereof.

In another embodiment, the technology of the present disclosure is a device, including a housing, having an exterior face, a retaining hook, pinned to the housing, having a hook surface with a curved profile, a tethering component, including a catch piece having a catch surface matched with the curved profile, a flexible strap, having a first strap end coupled to the housing and a second strap end coupled the tethering component, a latch bolt secured within the housing, having a predetermined range of motion defined by the housing, and accessible through an opening in the exterior face, and a magnetic clasp, having a first component, disposed within the housing and a second component disposed separately from the housing, the second component being magnetically engageable with the first component.

In a variation of this embodiment, the second component is secured to the tethering component.

In a variation of this embodiment, the tethering component is securable to a secondary device via a fastener.

In a variation of this embodiment, the housing includes a deformable material disposed about a perimeter of the housing.

In a variation of this embodiment, the latch bolt is biased by a spring.

In a variation of this embodiment, the predetermined range of motion is defined such that a portion of the latch bolt is extendable beyond the housing.

### BRIEF DESCRIPTION OF THE DRAWINGS

The accompanying figures, where like reference numerals refer to identical or operationally similar elements throughout the separate views, together with the detailed description below, are incorporated in and form part of the specification, and serve to further illustrate embodiments of concepts that include the claimed technology and explain various principles and advantages of those embodiments.

FIG. 1 illustrates a view of a device having a port cover, the device secured to a tablet, according to embodiments of the present disclosure.

FIG. 2 illustrates a detached view of the device having a port cover of FIG. 1, according to embodiments of the present disclosure.

FIG. 3 illustrates a view of a port cover with certain components hidden, such that other components may be easily viewed, according to embodiments of the present disclosure.

FIG. 4 illustrates a view of a device and a port cover in the closed configuration, according to embodiments of the present disclosure.

FIG. 5 illustrates a view of a device and a port cover in the intermediate-open configuration, according to embodiments of the present disclosure.

FIG. 6 illustrates a view of the device of FIG. 1 and a port cover in an open-retained configuration and with cables inserted in the ports, according to embodiments of the present disclosure.

FIG. 7 illustrates a mechanical latching mechanism of a port cover, according to embodiments of the present disclosure.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the technology of the present disclosure.

The apparatus and method components have been represented where appropriate by conventional symbols in the drawings, showing only those specific details that are pertinent to understanding the embodiments of the technology of the present disclosure so as not to obscure the disclosure with details that will be readily apparent to those of ordinary skill in the art having the benefit of the description herein.

### DETAILED DESCRIPTION

Provided herein are port covers (e.g., port cover 120, port cover system, device, etc.) which may be advantageously applied to numerous devices (e.g., device 100) to prevent ingress of water, particulate matter, and other elements into a porting area of a device. The cover may also prevent accidental contact with the ports that might damage them by shock, impact, or abrasion. The port covers disclosed herein are engageable with compatibly configured porting areas, and are selectively disengageable, such that access is provided to the porting area, while the port cover remains coupled to the device. In some embodiments, the port cover includes a magnetic clasp, such that the port cover may be stowed and secured to the device when not engaged with the porting area of the device, such that movement of the device does not affect the position of the port cover relative to the device.

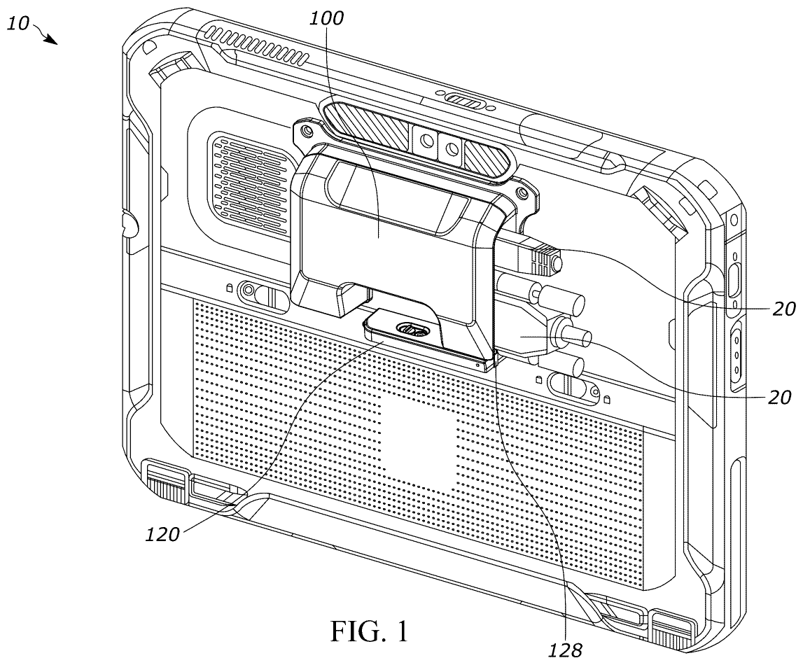

FIG. 1 illustrates a view of a device 100 (e.g., secondary device) and a port cover 120 (e.g., device, port cover system). As illustrated in FIG. 1, the device 100 is a back module accessory for a tablet 10, the device 100 supporting ported connections for cables 20. This disclosure further contemplates embodiments in which the device 100 is an electronic device, personal electronic device, mobile computer, wearable computer, handheld electronic device, tablet, electronic accessory device, similar device, or an accessory device which is coupled to one of the aforementioned devices, where the device 100 supports ported connections for cables 20.

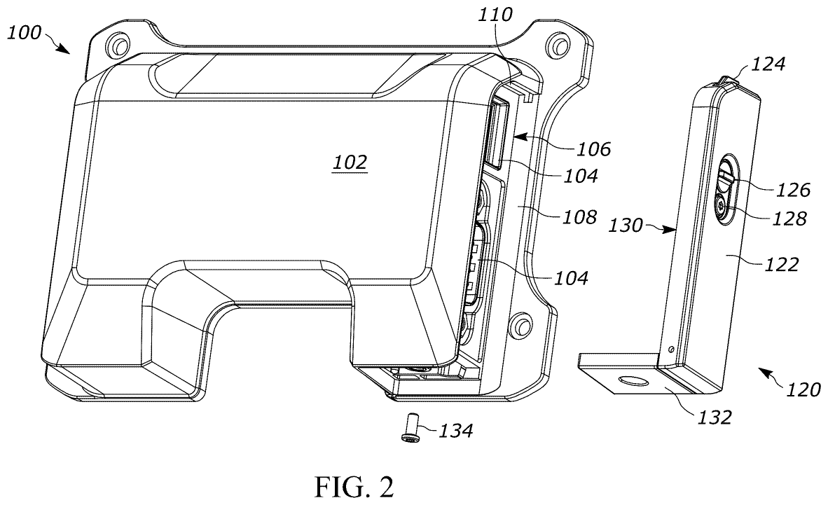

FIG. 2 illustrates an exploded view of the device 100 and the port cover 120. According to some embodiments, the device 100 includes a defined porting area 106, which is recessed into the body 102 of the device 100 and includes ports 104 disposed therein. Embodiments wherein the ports are disposed on a non-recessed external surface of the body 102 of the device 100 are also contemplated.

The ports 104 may be configured to be connectable with various electrical and optical cables via various conventional cable connectors. The ports 104 may include, e.g., a high definition media interface (HDMI) port, a universal series bus (USB) port, a registered jack-45 (RJ-45) port, a registered jack-11 (RJ-11) port, a tip, ring and sleeve (TRS) connector port, a video-graphics array (VGA) port, a digital video interface (DVI) port, a display port, component video ports, a serial port, and a Recommended Standard 232 (RS-232) port, or other conventional port types and configurations.

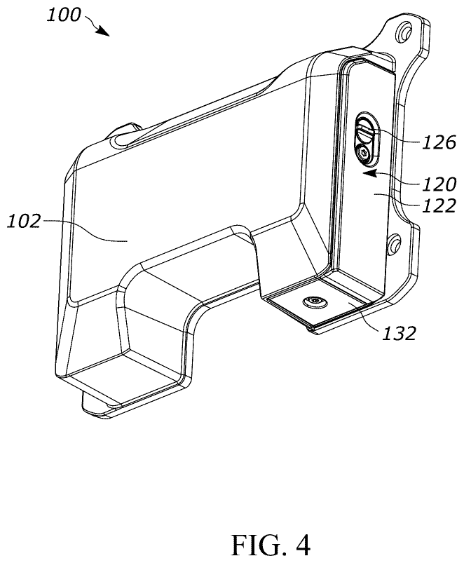

The port cover 120 is configured to block access to the ports 104 and the porting area 106 (e.g., block user access, or isolate the ports 104 from the environment) when the port cover 120 is in the closed configuration (See FIG. 4). The port cover 120 is further configured to not block access to the porting area 106 and the ports 104 when not in the closed configuration (e.g., permitting access to the porting area 106), e.g., when it is in an open configuration, but still mechanically attached to the device 100.

The port cover 120 is matched with an outer profile of porting area 106, so as to cover the porting area 106. As illustrated, the porting area 106 includes an outer wall 108, which may be formed by one or more constituent walls, having features of various dimensions and curvatures. In some embodiments, the outer wall 108 includes three or more constituent walls. In some embodiments, the porting area 106 is substantially rectangular, substantially circular, or substantially ovoid. Other shapes of the porting area 106 are also contemplated. The outer wall 108 may define the outer profile, to which a portion of the port cover 120 is matched so as to conform with and be engageable with the porting area 106.

In some embodiments, the port cover 120, or a portion thereof, is wholly or partially insertable into the porting area 106, such that the outer perimeter of port cover 120 abuts the outer wall 108 of the porting area 106, which may substantially seal the porting area 106 off from the environment. In some examples, the port cover 120, or a portion thereof, may be configured to remain substantially external to the porting area 106, and cover the porting area 106 by abutting the body 102 of the device 100 about and proximately to the porting area 106. In some embodiments the port cover 120 may include a deformable material disposed about a perimeter of the housing (e.g., the cover plate 122, the back plate 130) which is configured to form a seal with the outer wall 108 of the porting area 106 or form a seal with the body 102 of the device 100.

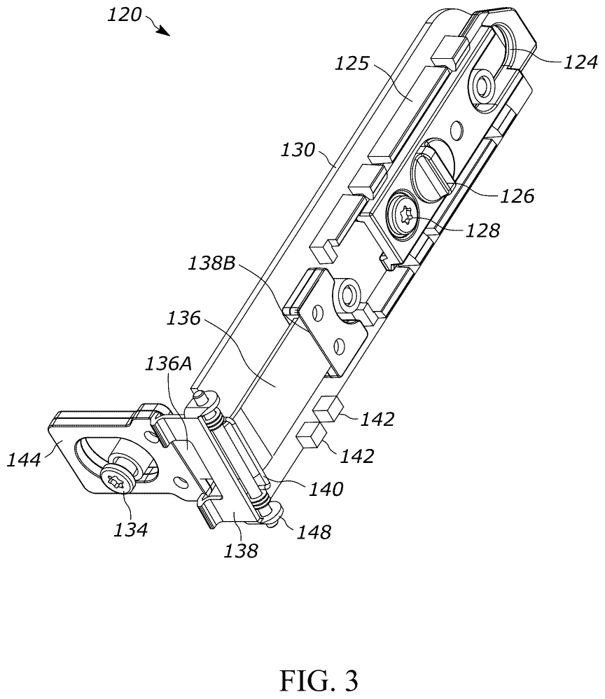

The port cover 120 may include one or more structural components which collectively form a housing. As illustrated in FIG. 1, an exterior face of the port cover 120 is provided by a cover plate 122. A back plate 130 may form another portion of the housing, and several components of the port cover 120 may be directly coupled to the back plate 130. In some examples, the port cover 120 includes a tether cover plate 132, which may conceal and secure the tethering component 144 (See FIG. 3) among other purposes. In some examples, the tether cover plate 132 may be referred to or regarded as a component of the housing. The port cover 120 may further include a fastener 134 by which the tether cover plate 132, among other components, may be coupled to the device 100.

The port cover 120 and the device 100 include a latching mechanism, including a latch bolt 124 coupled to the port cover 120, and a keeper 110, which is coupled to the porting area 106, according to embodiments of the present disclosure. The latch bolt 124 is translatable through a predetermined range of motion, such that a portion of the latch bolt is configured to protrude beyond a cover plate 122 so as to interface with the keeper 110 when the port cover 120 is in the closed configuration. The latch bolt 124 is in the engaged position when the latch bolt 124 and the keeper 110 contact one another in such a manner that the system formed therebetween resists forces (e.g., forces in a direction perpendicular to the predetermined range of motion) applied to the port cover 120 in a direction which might otherwise dislodge the port cover 120 from the porting area 106. When the latch bolt 124 is not in the engaged position, the latch bolt is in the disengaged position, a term which may encompass a set of positions of the latch bolt 124 within the predetermined range of motion where the latch bolt 124 is not extended beyond the housing of the port cover 120 to a sufficient extent to interface with the keeper 110.

In some examples the predetermined range of motion of the latch bolt 124 is governed by an opening in the cover plate 122 through which a portion of the latch bolt 124 is accessible. The portion of latch bolt 124 which extends through the opening in the cover plate 122 includes a protrusion 126 such that the latch bolt 124 is accessible to be translated by a user. The protrusion 126 may abut the edges of the opening in the cover plate at limiting points of the predetermined range of motion, thus preventing further translation towards the edge.

In some examples, the latch includes a lock screw 128, which may block the latch bolt 124 from translation, a feature that may be employed to retain the latch bolt 124 in the engaged position.

In some examples, the keeper 110 is a protrusion or lip emanating from the outer wall 108 of the porting area 106. In some examples the keeper 110 is a hole or detent defined into the outer wall 108 of the porting area 106. In some examples the keeper is secured to the outer wall 108 of the porting area 106, and in other examples the keeper 110 is integrally formed with the outer wall 108 of the porting area 106.

FIG. 3 illustrates the port cover 120, where the cover plate 122 and tether cover plate 132 have been hidden, such that certain features are viewable, according to embodiments of the present disclosure. In some examples, the back plate 130 includes rails 125 along which the latch bolt 124 is translatable.

The port cover 120 further includes a tethering component 144, which is coupled to the device 100 via the fastener 134 and the tether cover plate 132. The tethering component 144 secures a flexible member 136 (e.g., tether, strap) at a first member end 136A, and a second member end 136B of the flexible member 136 is secured to the back plate 130. Embodiments where the flexible member is secured to the cover plate or other portions of the port cover 120 are also contemplated. The flexible member 136 retains a coupling between the port cover 120 and the device 100 (via the tethering component 144) regardless of the engagement of the latch (e.g., the latch bolt 124 and keeper 110) or the engagement of the magnetic clasp (e.g., cover magnetic component 142, and device magnetic component 146). According to some embodiments, the flexible member may be constructed of nylon, rubber, metal tape, flexible plastics, silicone, and other suitable flexible materials.

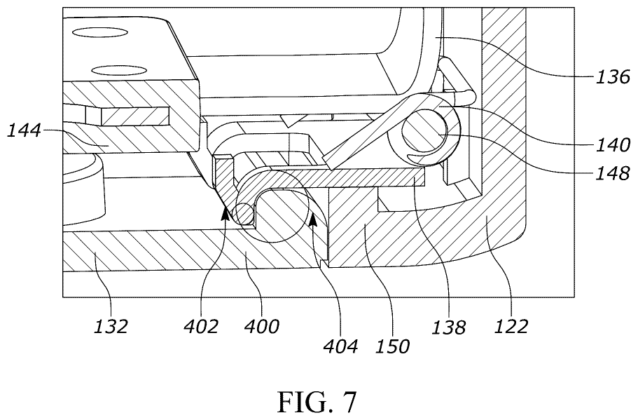

In addition to the latch, the port cover 120 may also be secured at a second point (e.g., distinct from the latch location) by a mechanical catch. In the illustrated embodiment, the mechanical catch is formed by a hook 138 and a catch piece 400, which is discussed in greater detail with respect to FIG. 7. In some examples, the mechanical catch may include a fixed protrusion or pin interfacing with a hole or detent, such that when the port cover 120 is in the closed configuration the mechanical catch restricts a degree of freedom of motion of the port cover 120. In this manner, the port cover 120 is securable at a first location of the porting area 106 via the latch bolt 124 and the keeper 110 and retained at a second location by the mechanical catch. In this manner, the latch and the mechanical catch secure the port cover 120 in the closed configuration such that the port cover 120 does not possess any degrees of freedom of motion with respect to the device. In such embodiments, the mechanical catch is substantially disengaged after the latch bolt is transitioned to the disengaged position, such that the port cover 120 is removable from the porting area 106, and the port cover 120 is retained to the device 100 solely by the flexible member 136.

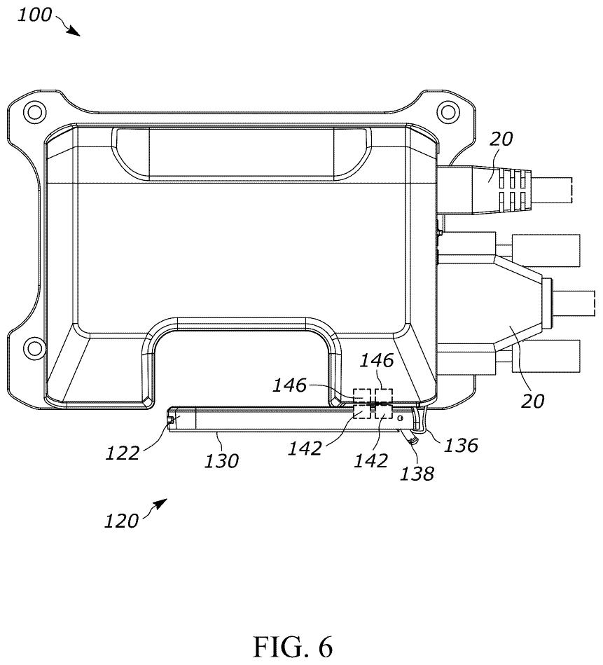

The port cover 120 may also house cover magnetic component(s) 142 (e.g., magnetic components, magnets) which are included in the magnetic clasp, which is discussed in greater detail with respect to FIG. 6.

FIG. 4 illustrates a view of the device 100 and the port cover 120 in the closed configuration, according to embodiments of the present disclosure. In the closed configuration, the port cover 120 blocks access to the porting area 106, thus preventing ingress of water, particulate matter, and other elements into a porting area of a device. In the closed configuration, the port cover 120 may also prevent accidental contact with the ports 104 that might damage the ports 104 by shock, impact, or abrasion. In the closed configuration, the latch (e.g., latch bolt 124 and keeper 110) is in the engaged configuration, and the mechanical catch (e.g., hook 138 and catch piece 400) is engaged.

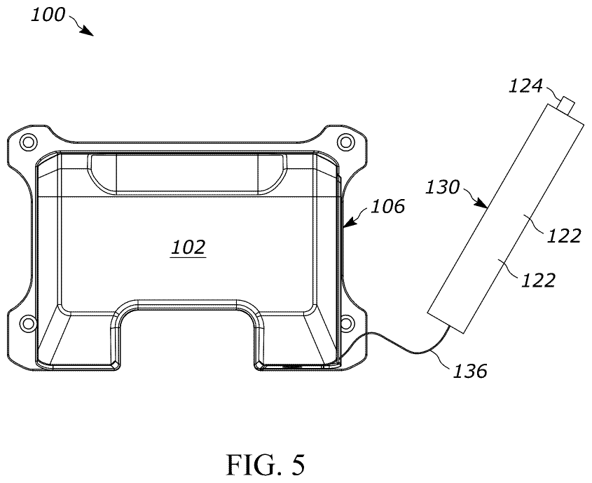

FIG. 5 illustrates a view of the device 100 and the port cover 120 in the intermediate open configuration, according to embodiments of the present disclosure. In the intermediate open configuration, the latch is in the disengaged configuration, the mechanical catch is not engaged, and the magnetic clasp is not engaged. The port cover 120 is connected to the device via the flexible member 136 and possesses a range of motion governed by the length of the flexible member 136. As the flexible member 136 is flexible or otherwise deformable, there exists a large range of possible positions that the port cover 120 in the intermediate-open configuration may take.

FIG. 6 illustrates a view of the device 100 and the port cover 120 in the open-retained configuration, according to embodiments of the present disclosure. In the open-retained configuration, the port cover 120 is coupled to the device 100 via a magnetic connection provided by the magnetic clasp. As used herein, the term “open-retained configuration” refers to the configuration in which the port cover 120 does not obstruct the porting area 106 (e.g., such that cables 20 may engage with the ports 104), and the port cover 120 is coupled to the device 100 via the magnetic clasp, such that the port cover 120 does not freely dangle by the flexible member 136.

In the illustrated embodiment, the external face of the cover plate 122 occupies a first plane when in the closed configuration, and the external face of the cover plate 122 occupies a second plane when the open-retained configuration. As illustrated, the first plane and the second plane are offset by 270 degrees of rotation, however, this disclosure contemplates embodiment wherein the body 102 of the device 100 and the port cover 120 are mutually configured such that the first plane and the second plane may be offset from one another by a degree of rotation in the range of 30 degrees to 300 degrees of rotation. Furthermore, this disclosure contemplates embodiments wherein the first plane and the second plane are rotationally offset from one another about one or more axis of rotation. According to one or more embodiment, the first plane and the second plane are rotational offset from one another by at least 180 degrees of rotation.

The magnetic clasp is formed by a cover magnetic component(s) 142 and a device magnetic component(s) 146. As illustrated, the cover magnetic component 142 includes two individual magnetic components, however embodiments where the cover magnetic component 142 has more or fewer magnetic components are contemplated. As illustrated, the device magnetic component 146 includes two individual magnetic components, however embodiments where the device magnetic component 146 has more or fewer magnetic components are contemplated. The device magnetic component 146 is coupled to or housed within the device 100, and in some examples the device magnetic component 146 is housed within the tethering component 144 or the tether cover plate 132. The cover magnetic component 142 is coupled to or housed by the port cover 120. The cover magnetic component 142 and the device magnetic component 146 are configured to be magnetically engageable, having a magnetic force of attracting therebetween sufficient to independently retain the port cover 120 to the device 100. In some examples, both the cover magnetic component 142 and the device magnetic component 146 are magnets. In some examples, the cover magnetic component 142 is a magnet and the corresponding device magnetic component 146 is a ferromagnetic component which is magnetized by the magnet, or vice versa.

In some embodiments where the device magnetic components 146 are coupled directly to the tethering component 144 or the tether cover plate 132, the port cover 120 may be modular, such that the port cover 120 is removable from the device (e.g., by removing the fastener 134).

FIG. 7 illustrates a view of the mechanical catch mechanism, according to embodiments of the present disclosure. According to one or more embodiments, the mechanical catch mechanism includes a hook 138 and a catch piece 400. In some examples, the catch piece 400 is integrally formed with, or coupled to, one of the tether cover plate 132, the tethering component 144, or the body 102 of the device 100. The hook 138 is configured to interface with the catch piece 400, such that when the hook 138 and the catch piece 400 are engaged with one another, and the port cover 120 is in the closed configuration, a degree of freedom of motion of the port cover 120 is restricted. When the port cover 120 is transitioned out of the closed configuration (e.g., the latch bolt 124 is transitioned to the disengaged position) the port cover 120 is rotatable about the catch piece 400 (via the hook 138) through a predetermined range of rotation, such that the porting area 106 becomes exposed and the port cover 120 is in the intermediate-open configuration. Once a limit of the predetermined range of rotation has been reached, the hook 138 disengages from the catch piece 400, and the port cover 120 is separable from the device 100, save for the flexible member 136.

In some examples, the hook 138 is mechanically coupled to the cover plate 122 or the back plate 130. In some examples, the hook 138 is integrally formed with one of the cover plate 122 and the back plate 130. In other examples, the hook 138 is fixed, pinned, or fastened to the one of the cover plate 122 and the back plate 130. In the illustrated embodiment, the hook 138 is pinned to the cover plate 122 (e.g., the hook has a rotational degree of freedom relative to the to the cover plate 122) via a pin 148. In some embodiments, the hook 138 may be biased by a spring 140. In FIG. 7, as well as other embodiments, the cover plate 122 forms a stop 150 for the hook 138, such that when the spring 140 and hook 138 system is at rest, the hook 138 is held is a fixed position between the biasing force provided by the spring 140 and the stop 150. In some examples, the spring 140 is a torsional spring wound about the pin 148 about which the hook 138 rotates.

According to some embodiments, the hook 138 includes a first contact surface 402, and the catch piece includes a second contact surface 404. The first contact surface 402 may be angled, chamfered, filleted, or otherwise include a curved profile or angular profile. The second contact surface may be angled, chamfered, filleted, or otherwise include a curved profile or angular profile. When transitioning the port cover 120 to the closed position, the mechanical catch is engaged by aligning the first contact surface 402 and the second contact surface 404 and providing an external force on the port cover 120 towards the device 100. The first contact surface 402 and the second contact surface 404 interface under the influence of the external force such that the hook 138 is forced to rotate about the pin 148 in a manner that counteracts the biasing force of the spring 140, such that the hook 138 slides over the catch piece 400 and the hook 138 engages the catch piece 400 such that the degree of freedom of motion of the port cover 120 is restricted.

In some examples, the hook 138 is rigidly fixed to, or integrally formed with the cover plate 122, and the body of the hook 138 has sufficient flexible and tensile properties to act as a spring, such that the spring 140 is not necessary to provide a biasing force on the hook 138. Said differently, the deformable quality of the hook 138 may provide for the hook 138 to elastically deform when forced towards the catch piece 400 and return to the undeformed position when the hook 138 engages the catch piece 400.

In the foregoing specification, specific embodiments have been described. However, one of ordinary skill in the art appreciates that various modifications and changes can be made without departing from the scope of the technology as set forth in the claims below. Accordingly, the specification and figures are to be regarded in an illustrative rather than a restrictive sense, and all such modifications are intended to be included within the scope of present teachings. Additionally, the described embodiments/examples/implementations should not be interpreted as mutually exclusive and should instead be understood as potentially combinable if such combinations are permissive in any way. In other words, any feature disclosed in any of the aforementioned embodiments/examples/implementations may be included in any of the other aforementioned embodiments/examples/implementations.

The benefits, advantages, solutions to problems, and any element(s) that may cause any benefit, advantage, or solution to occur or become more pronounced are not to be construed as a critical, required, or essential features or elements of any or all the claims. The claimed technology is defined solely by the appended claims including any amendments made during the pendency of this application and all equivalents of those claims as issued.

Moreover, in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain manner is configured in at least that manner but may also be configured in arrangements that are not listed.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter may lie in less than all features of a single disclosed embodiment. Thus, the following claims are hereby incorporated into the Detailed Description, with each claim standing on its own as a separately claimed subject matter.

1. A latching port cover system for a device having a port; comprising:
a recessed porting area in which the port is disposed, the recessed porting area having an outer profile defined by an outer wall;
a keeper mechanically coupled to the outer wall;
a cover, matched with the outer profile, having an open-retained configuration permitting access to the port and a closed configuration covering the port;
a latch bolt mechanically coupled to the cover, translatable between an engaged configuration and a disengaged configuration, wherein when the latch bolt is in the engaged configuration, the latch bolt interfaces with the keeper, retaining the cover in the closed configuration;
a flexible member, having a first member end mechanically coupled to the cover and a second member end mechanically coupled to the device; and
a magnetic clasp, including a first portion mechanically coupled to the device and a second portion mechanically coupled to the cover, the magnetic clasp retaining the cover in the open-retained configuration when the first portion magnetically engages with the second portion.

2. The latching port cover system of claim 1, wherein the cover and the device interface via a mechanical catch distinct from the latch bolt and keeper, and the mechanical catch restricts a degree of freedom of motion of the cover when the cover is in the closed configuration.

3. The latching port cover system of claim 2, wherein the mechanical catch includes a hook and a catch piece, wherein the hook is coupled to the cover and the catch piece is coupled to the device, and when the latch bolt is in the disengaged configuration the cover is rotatable about the catch piece via the hook through a predetermined range of rotation, and the cover is transitioned out of the closed configuration when rotated about the catch piece.

4. The latching port cover system of claim 3, wherein the hook is configured such that when the cover is rotated beyond the predetermined range of rotation, the hook disengages from the catch piece.

5. The latching port cover system of claim 3, wherein the hook is coupled to the cover via a pinned connection and biased by a spring such that when the cover is in the closed configuration the hook is biased towards the catch piece and remains engaged with the catch piece.

6. The latching port cover system of claim 5, wherein the hook includes a chamfered or filleted surface, such that when the cover is not in the closed configuration and the hook is aligned with the catch piece and externally biased towards the catch piece, the spring is counteracted such that the hook rotates about the pinned connection and engages with the catch piece.

7. The latching port cover system of claim 3, wherein the second member end of the flexible member is coupled to the device by a tethering component which is coupled to the device, and the tethering component includes the catch piece.

8. The latching port cover system of claim 7, wherein the tethering component houses the second portion of the magnetic clasp.

9. The latching port cover system of claim 7, wherein the tethering component is mechanically coupled to the device via a fastener, such that the cover is separable from the device when the fastener is removed from the tethering component.

10. The latching port cover system of claim 1, wherein the keeper is selected from a group consisting of a detent, a recess, a protrusion, and a hole.

11. The latching port cover system of claim 1, wherein the keeper is integrally formed with the outer wall.

12. The latching port cover system of claim 1, wherein the recessed porting area of the device includes a plurality of ports, each port of the plurality of ports selected from a group consisting of a high definition media interface (HDMI) port, a universal series bus (USB) port, a registered jack-45 (RJ-45) port, a registered jack-11 (RJ-11) port, a tip, ring and sleeve (TRS) connector port, a video-graphics array (VGA) port, a digital video interface (DVI) port, a display port, component video ports, a serial port, and a Recommended Standard 232 (RS-232) port.

13. The latching port cover system of claim 1, wherein the outer wall of the recessed porting area is defined by three or more constituent walls, and the outer profile of the outer wall with which the cover is matched is defined by two or more of the three or more constituent walls.

14. The latching port cover system of claim 1, wherein the recessed porting area is substantially rectangular.

15. The latching port cover system of claim 1, wherein when the cover is in the closed configuration the cover is defined in a first plane, when the cover is the open-retained configuration, the cover is defined in a second plane, and the first plane and the second plane are offset from one another by at least 180 degrees.

16. The latching port cover system of claim 15, wherein the first plane and the second plane are offset by at least 270 degrees.

17. The latching port cover system of claim 1, wherein the cover includes a deformable material disposed about a portion of the cover which abuts the outer wall when the cover is in the closed configuration.

18. The latching port cover system of claim 1, wherein the latch bolt is biased towards the engaged configuration by a spring.

19. The latching port cover system of claim 1, wherein the flexible member is a flexible strap.

20. The latching port cover system of claim 1, wherein the flexible member is constructed of a material selected from a group consisting of nylon, metal tape, rubber, silicone, and combinations thereof.

21. A device, comprising:
a housing, having an exterior face;
a retaining hook, pinned to the housing, having a hook surface with a curved profile;
a tethering component, including a catch piece having a catch surface matched with the curved profile;
a flexible strap, having a first strap end coupled to the housing and a second strap end coupled the tethering component;
a latch bolt secured within the housing, having a predetermined range of motion defined by the housing, and accessible through an opening in the exterior face; and
a magnetic clasp, having a first component, disposed within the housing and a second component disposed separately from the housing, the second component being magnetically engageable with the first component.

22. The device of claim 21, wherein the second component is secured to the tethering component.

23. The device of claim 21, wherein the tethering component is securable to a secondary device via a fastener.

24. The device of claim 21, wherein the housing includes a deformable material disposed about a perimeter of the housing.

25. The device of claim 21, wherein the latch bolt is biased by a spring.

26. The device of claim 21, wherein the predetermined range of motion is defined such that a portion of the latch bolt is extendable beyond the housing.
